(19) United States
(12) Patent Application Publication
(10) Pub. No.: US 2025/0112591 A1
(43) Pub. Date: Apr. 3, 2025

(54) SOLAR CELL TEST METHOD, SOLAR CELL TEST DEVICE AND COMPUTER-READABLE MEDIUM

(71) Applicant: WAVELABS SOLAR METROLOGY SYSTEMS GMBH, Leipzig (DE)

(72) Inventor: Donald Andrew Locker CLUGSTON, Leipzig (DE)

(73) Assignee: WAVELABS SOLAR METROLOGY SYSTEMS GMBH, Leipzig (DE)

(21) Appl. No.: 18/833,733

(22) PCT Filed: Jan. 26, 2023
(86) PCT No.: PCT/DE2023/100058

§ 371 Date: Jul. 26, 2024

(30) Foreign Application Priority Data
Jan. 28, 2022 (DE) 102022102030.4

(51) Int. Cl. H02S 50/10; G01R 19/165; G01R 27/26

(52) U.S. Cl. CPC H02S 50/10; G01R 19/16571; G01R 27/2605

(57) ABSTRACT

A solar cell test method includes applying a varying electrical voltage at a contacted solar cell and measuring an associated current depending on the applied voltage or applying a varying electrical current and measuring an associated voltage depending on the applied current. The applied voltage or the applied current are varied in such a way that the applied or measured voltage initially flows in a forwards direction through voltage values from a lower to a higher voltage and then in a backwards direction through voltage values from a higher to a lower voltage. In the forwards direction, the voltage values and the associated current values are arranged on a forwards current/voltage curve, and in the backwards direction, the voltage values and the associated current values are arranged on a backwards current/voltage curve. A power parameter, of the solar cell is derived from the voltage values and associated current values of the forwards current/voltage curve and the voltage values and associated current values of the backwards current/voltage curve. Within a first voltage range, in the backwards direction, the voltage values have smaller spacings on average than the voltage ranges neighbouring the first voltage range.

The invention relates to a solar cell test method, a solar cell test device and a computer-readable medium for implementing the solar cell test method.

Highly efficient silicon solar cells are known to have a high “capacitance”. This means that they react to changes in the voltage at a slower rate. When measuring the current-voltage characteristic curve (I-U characteristic curve) of a solar cell, capacitive errors occur due to this effect if the voltage value specified by the measuring device changes too quickly during the characteristic curve measurement and the solar cell does not adjust sufficiently quickly to a change in the applied voltage or the current intensity. This problem is becoming increasingly common in power measurements of crystalline silicon solar cells or solar modules and is called the hysteresis effect. The effect is observed with increasing measuring speed and increasing efficiency, i.e. especially at high efficiencies, in crystalline silicon solar cells, but can also be of importance in other solar cells. The faster the measurement and the better the solar cell, the stronger the effect.

In order to measure the I-U characteristic curve, contact is made with the solar cell and a measuring voltage, which runs through a voltage measuring range, is applied to the contacts. Usually, the solar cell is irradiated during the measurement with a light source that simulates the solar spectrum (e.g. a sun according to IEC 60904), and the applied voltage is selected such that the solar cell runs through operating points between open-circuit voltage (Voc) and short-circuit current (Isc), including the maximum power point (MPP). When the solar cell is irradiated or illuminated, this I-U characteristic curve is in the quadrant of interest between Voc on the voltage axis and the Isc on the current axis. Usually, the I-U characteristic curve for an illuminated solar cell runs from Isc (Isc is about 1.6 amperes for a conventional solar cell with an irradiation with 1 sun) at an applied voltage of U=0 volts, approximately parallel to the voltage axis, to a kink area or knee area, where the current drops as the gradient increases. Below the knee area, the I-U characteristic curve drops steeply to the voltage axis, which crosses it at Voc, which is between 0.65 V and 0.75 volts in conventional solar cells. The knee area, or knee for short, is the area around a knee voltage, which is also called threshold voltage or kink voltage in diodes.

The I-U characteristic curve is referred to below as the steady-state I-U characteristic curve or steady-state current-voltage characteristic curve (also known as steady-state IV curve) if, when measured at each set voltage value of the solar cell, sufficient time was allowed for flowing transient currents to decay and a state of equilibrium to be formed during a transient phase. For the sake of simplicity, this can also simply be referred to as an I-U characteristic curve. The duration of the waiting time required for each point on the I-U characteristic curve in order to obtain this state of equilibrium depends on properties of the solar cell, such as its material composition, structure, doping and doping distribution, and the like.

If the I-U characteristic curve is run through too quickly, i.e. in a fast measuring run, in which the applied voltage or the applied current varies too quickly, the measured current-voltage curve (I-U curve) deviates from the steady-state current-voltage characteristic curve, especially at the MPP. In addition, a hysteresis is formed, since the deviation depends not only on the measuring speed, but also on the measuring direction. If the voltage is run through from a lower voltage value to a higher voltage value, this corresponds to running through the I-U characteristic curve from a short-circuit state (Isc) to an open-circuit state (Voc) when the solar cell is illuminated. In the situation with hysteresis, a curve is obtained here, which is referred to below as a forward current-voltage curve or forward curve for short and runs below the I-U characteristic curve in the current-voltage diagram. If, on the other hand, the voltage is run through from a higher voltage value to a lower voltage value, this corresponds to running through the I-U characteristic curve from the open-circuit state to the short-circuit state when the solar cell is illuminated.

In the situation with hysteresis, a curve is obtained here, which is referred to below as a reverse current-voltage curve or reverse curve for short and runs above the I-U characteristic curve in the current-voltage diagram. If a complete pass is thus effected, in which the voltage at the solar cell is run through from zero to a maximum value and back to zero, then a hysteresis results.

Because the maximum power point (MPP), which is so important for the evaluation of a solar cell, is arranged on the actual, steady-state I-U characteristic curve and the deviations of the forward curve and the reverse curve from the I-U characteristic curve are particularly pronounced in the region of the MPP, the handling of the forward or reverse curve instead of the I-U characteristic curve would result in incorrect measurement results, for example when testing solar cells in order to determine the solar cell efficiency. As explained above, this problem is exacerbated by the ever-improving solar cells, because the hysteresis effect is more pronounced in solar cells with better efficiencies.

The hysteresis effect can be avoided by slowly running through the I-U characteristic curve. In the case of particularly good solar cells, however, several seconds would have to be spent for a pass in order to avoid hysteresis. In modern production systems, however, the time available for solar cell testing in a production line is only about 40 ms. A hysteresis-free measurement is therefore not achievable. An attempt to explain the behavior of the solar cell with an I-U characteristic curve with hysteresis using a model based on capacitive effects was made in the publication “Assessing Transient Measurement Errors for High-Efficiency Silicon Solar Cells and Modules”, R. A. Sinton, IEEE Journal of Photovoltaics (November 2017), hereinafter referred to as [Sinton 2017]. It proposes and explains how the steady-state current-voltage characteristic curve or at least an approximation to this characteristic curve can be calculated from the two previously determined curves with hysteresis, namely the forward curve and the reverse curve. This procedure is not always readily applicable. This method continues to produce erroneous results when scanning very efficient solar cells quickly.

The object of the invention is to provide a method and devices for solar cell testing, with which electrical properties of solar cells can be determined quickly and reliably.

The object is achieved according to the invention by a solar cell test method having the features of claim 1, by a solar cell test device having the features of claim 20 and by a computer-readable medium having the features of claim 21. Advantageous developments of the invention are listed in the subclaims.

According to one aspect of the invention, a solar cell test method is thus proposed. Based on the possibility of calculating the steady-state current-voltage characteristic curve from the forward curve and the reverse curve, the inventors have found that in certain situations the reverse curve shows an unsteady behavior. For example, in the area of the knee in the I-U characteristic curve, especially near the operating point of maximum power (MPP), the reverse curve suddenly jumps in the direction of the steady-state current-voltage characteristic curve or even onto the steady-state current-voltage characteristic curve. If the forward curve and the reverse curve are used to calculate the steady-state current-voltage characteristic curve, and the steady-state current-voltage characteristic curve is in turn used to derive electrical parameters of the solar cell on its basis, then this effect results in a falsification of the result. The inventors have found that this jump in the reverse curve occurs in particular during fast passes in particularly efficient solar cells. This effect is reminiscent of the behavior of a step recovery diode, also called a snap-off diode. The phenomenon of “step recovery” was first recognized in 1960 by the scientists Boff, Moll and Sheen.

In the case of forward-polarized diodes or solar cells, the charge caused by diffusion capacitance is represented by equation (1) in [Sinton 2017]. The analysis in [Sinton 2017] is applicable to voltage values around or above the MPP and for small changes in the voltage, i.e. for small voltage value steps. At lower voltage values, the junction capacitance exceeds the diffusion capacitance and the component can behave qualitatively differently, namely the “step recovery” effect can occur in particular. If the applied voltage changes too quickly from a higher to a lower voltage value during a reverse curve in the critical range (first voltage range), the applied voltage is temporarily lower than the junction voltage. Under these circumstances, the potential difference between the junction and the terminals of the solar cell is negative, and this potential causes currents opposite to the diode current. The current is equal to the difference between the junction voltage and the applied voltage, divided by the resistance over the component, according to Ohm's law. The stored charge flows out of the component at an approximately constant rate. The voltage at the junction changes quasilinearly. As soon as the stored diffusion charge has drained, the voltage at the junction changes very quickly. The rate of change can be hundreds of times higher than in the quasilinear range. This effect is used in step recovery diodes to generate very short pulses.

This effect occurs only in the reverse pass, resulting in a fundamental asymmetry between the forward curve and the reverse curve. In the photovoltaic literature and in the photovoltaic industry as a whole, this effect has not yet been taken into account.

The invention is now based on the consideration of finding the aforementioned knee area, in which the operating point of maximum power (MPP) is located with appropriate irradiation of the solar cell, or in which the critical area, i.e. the area at risk of the “step recovery” effect, is located in the case of a non-illuminated solar cell. This knee area is referred to below as the first voltage range. The knee area is thus the transition area between the approximately horizontal part of the I-U characteristic curve with a very low gradient and the steep part, which ends in Voc. Although it can also be referred to as a kink or knee area, this transition area is rounded and rather curved, at least when current is plotted linearly against voltage, and is also called the knee area (“knee”) in English. This term shall also be used in the following. A second consideration is to approach this knee area with smaller spacings during the reverse pass, i.e. when determining the reverse curve, in order to avoid the unstable jump in the reverse curve. Within the first voltage range, use is therefore made in the reverse pass of voltage values, the spacings between which are on average smaller than the spacings in adjacent voltage ranges above and below the first voltage range that adjoin this first voltage range. The reverse curve determined in this manner is continuous and can be used together with the forward curve to calculate the steady-state current-voltage characteristic curve. In the case of the continuous reverse curve, the voltage does not necessarily have to decrease monotonously, but may also increase in a locally limited manner in certain embodiments, in particular when the boundary to the previously described area at risk of the “step recovery” effect has been crossed. Preferably, the voltage is increased briefly if it is determined that an excessively fast discharge occurs, that is to say the diffusion charge drains too quickly. For example, if the voltage is reduced from 0.6 V to 0.55 V in the reverse pass and the result determined is an excessively fast discharge, the voltage can be increased to 0.56 V again without leaving the reverse pass. This means that reference is made to a reverse pass in particular when the voltage is changed from a higher value to a lower value.

According to one preferred configuration, the voltage values in the forward pass essentially have no constant spacings. It may also be advantageous if the voltage value spacings in the forward pass differ from the voltage value spacings in the reverse pass.

One or more electrical parameters of the solar cell, in particular a power parameter, can be derived from the steady-state current-voltage characteristic curve. The power parameter is, for example, the maximum power of the solar cell or the efficiency of the solar cell. Since such a parameter can be derived from the steady-state current-voltage characteristic curve, which in turn is calculated from the forward curve and the reverse curve, it is basically possible to calculate the electrical parameter directly from the forward curve and the reverse curve without having to determine the steady-state current-voltage characteristic curve beforehand. According to one preferred embodiment, however, it is provided that the steady-state current-voltage characteristic curve or a part of the steady-state current-voltage characteristic curve is calculated from the voltage values and associated current values of the forward current-voltage curve and the voltage values and associated current values of the reverse current-voltage curve. For example, it is possible to calculate a part of the steady-state current-voltage characteristic curve that is outside the first voltage range. The electrical parameter can then be determined from the steady-state current-voltage characteristic curve calculated in this way.

If it is stated below that the forward curve or the reverse curve is used, for example, to calculate the steady-state current-voltage characteristic curve from these curves, then this means that the corresponding voltage values and associated current values of these curves are used.

An operating point of a solar cell can be set by applying a voltage to the contacts of the solar cell by means of a voltage source and measuring a current value which is then established. This current-voltage pair then forms a point of the current-voltage characteristic curve or the current-voltage curve that is currently being measured. However, it is also possible to apply or set a current value to/at the contacts using a current source. The specified current value then results in a voltage value being established at the contacts, which voltage value is measured. Here, too, the current-voltage pair determined in this way forms a point of the current-voltage characteristic curve or the current-voltage curve that is currently being measured. In practice, the voltage present across the solar cell is also advantageously measured when a voltage value is set at the contacts by means of the voltage source. This is carried out in order to avoid falsifications on the measured characteristic curve/curve caused by voltage drops across line and contact resistances.

According to the invention, the voltage values within the first voltage range having smaller spacings than the voltage values before and/or after them during the reverse pass. If a second voltage range denotes voltage values above the first voltage range, i.e. higher voltage values, and a third voltage range denotes voltage values below the first voltage range, i.e. lower voltage values, then this means that, preferably within the second voltage range and/or within the third voltage range, the voltage values have on average a greater spacing than in the first voltage range. This has the advantage that the measuring points along the reverse pass in voltage ranges two and three are comparatively far apart and can be run through very quickly and are closer in this critical first voltage range, and so a faster pass can be achieved overall.

In one advantageous embodiment, in the reverse pass within a fourth voltage range directly below the first voltage range, the voltage values on average still have a larger spacing than in the first voltage range. However, the spacings in the fourth voltage range are advantageously lower on average than in the second and/or the third voltage range. In this case, the first voltage range downwardly adjoins a fourth voltage range and upwardly adjoins a second voltage range, while the fourth voltage range is between the first voltage range and the third voltage range.

Advantageously, it is provided that the voltage values have continuously decreasing spacings within the first voltage range in the reverse pass. For example, the spacings may decrease parabolically. This has the advantage that, although a careful approach to the critical point is made, the measurement is accelerated because the spacings are increased further away from this critical point.

Preferably, it is provided that the reverse pass is terminated after running through the first voltage range and/or after running through the fourth voltage range. For example, it can be assumed here that the further course of the reverse curve is so close to the course of the forward curve that these curves practically coincide. In this case, it is unnecessary to continue scanning the reverse curve because its further course is already known. For example, it may be sufficient to carry out the reverse pass only until Isc is reached. Isc may have been determined here from the forward pass.

According to a simplified embodiment, the first voltage range is predetermined. This means in particular that the first voltage range is predetermined before the start of the solar cell test method, i.e. its associated voltage values are stored in a memory, for example. Preferably, the first voltage range is predetermined for a certain type of solar cell or for a certain category of solar cells. For example, the category of solar cell can be determined by means of a luminescence value which is determined by means of a luminescence measurement. In this case, the luminescence value can include results of the luminescence measurement such as brightness and/or topography. Alternatively or cumulatively, other parameters can be used to categorize the solar cells, such as the type and size of the solar cell.

Alternatively, instead of a predetermined first voltage range, it is also possible to predetermine an initial voltage which characterizes the first voltage range, because it forms, for example, the beginning of the first voltage range. This is therefore the voltage value from which the voltage value spacings are smaller than before in the reverse pass.

According to one advantageous development, the first voltage range is determined by means of the voltage values and associated current values of the forward current-voltage curve. This means that the forward current-voltage curve determined in the forward pass is used to determine the first voltage range, i.e. in particular the knee area.

The voltage values and voltage ranges described herein preferably refer to the contact voltage applied to the solar cell, i.e. to the solar cell contacts. The emitter voltage Ve can be calculated from the contact voltage V and the current I using the following formula: Ve=V−I*Rs. Here, Rs is a series resistance that takes into account the ohmic resistance of the solar cell contacts and solar cell layers.

According to one preferred embodiment, the first voltage range is derived from at least one first emitter voltage value. In other words, an emitter voltage value or an emitter voltage range may first be selected as predetermined. For example, the emitter voltage can be determined from the forward current-voltage curve for each current-voltage pair (I, V) using the formula above. The emitter voltage value, which is closest to a selected emitter voltage value (e.g. 500 mV), can then be selected therefrom. The contact voltage value or voltage value is then taken from the associated current-voltage pair (I, V). According to one expedient configuration, it is provided that those voltage values and associated current values of the forward current-voltage curve, for which deviations of the current values from a short-circuit current value are within a predefined first current difference range, are determined as the first voltage range. The I-U characteristic curve is approximately horizontal, i.e. parallel to the voltage axis, starting from the short-circuit current value Isc. This also applies approximately to the forward curve and the reverse curve. Only when approaching the knee area do these curves begin to deviate from the horizontal. A deviation from Isc therefore indicates an approach to the knee area. If the current value has reached an initial current value of the first current difference range in the forward pass, then it can be assumed that the deviation from Isc is of an order of magnitude for which the knee area has presumably been reached. In this configuration, the first current difference range along the current axis thus corresponds to the first voltage range along the voltage axis. The first current difference range, i.e. its initial current value and its final current value or its size, is preferably determined on the basis of the determined forward curve.

According to a preferred determination method for the first current difference range, the forward pass is carried out up to a maximum voltage value which may be in particular Voc or a voltage value near Voc. An associated current value is measured for this maximum voltage value. It should be noted that, in the case of a non-illuminated solar cell, the current value associated with Voc is also not equal to zero. In any case, the current value range between this current value measured at the maximum voltage value and the short-circuit current value (Isc) is defined as the total current value range. Now, the first current difference range is selected such that it begins at a distance of a first fraction, preferably 0.5%, 1% or 2%, of the total current value range from the short-circuit current value (Isc) and ends at a distance of a second fraction, preferably 5%, 10% or 15%, of the total current value range from the short-circuit current value. In other words, the initial current value of the first current difference range is at a distance of the first fraction of the total current value range from Isc, while the final current value of the first current difference range is at a distance of the second fraction of the total current value range from Isc.

In addition to this procedure just described for determining the current difference range and then the first voltage range, other algorithms can be used to determine the optimum spacings between the voltage values on the reverse curve.

According to one preferred configuration, it is provided that one or more capacitance values for the capacitance of the solar cell are determined point by point from one or more voltage values and associated current values of the forward current-voltage curve and/or the reverse current-voltage curve, wherein the voltage values during the reverse pass and/or a pass speed of the reverse pass is/are selected from the capacitance values. In other words, the capacitance is calculated here at each point of the respective current-voltage curve or a section of the respective current-voltage curve.

According to one preferred embodiment, it is provided that the steady-state current-voltage characteristic curve or a part of the steady-state current-voltage characteristic curve is calculated from an individual voltage value and the associated individual current value of the forward current-voltage curve and the voltage values and associated current values of the reverse current-voltage curve.

Preferably, the reverse pass is paused when the current value reaches the short-circuit current value (Isc) or exceeds the short-circuit current value (Isc). The reverse pass is then subsequently continued when the current value falls below the short-circuit current value (Isc) again. The reverse pass is paused in such a way that the contact voltage is kept constant until the short-circuit current value is undershot again. In other words, this can take place such that, in the reverse pass, the voltage is reduced, starting at Voc, until the current reaches and/or exceeds Isc. In this situation it is assumed that the knee area is reached. The voltage should then be kept constant until the current falls below Isc again. In this case, the constant voltage value can be the voltage value at which the current Isc was reached and/or exceeded, or a slightly higher voltage value.

According to one preferred embodiment, the voltage values are selected during the reverse pass in such a way that the solar cell is discharged during the reverse pass at substantially the same rate at which it was charged at the corresponding point in the forward pass.

Advantageously, the voltage values are selected during the reverse pass in such a way that, for each operating point (Vrvs, Irvs) on the reverse curve, a corresponding operating point (Vfwd, Ifwd) on the forward curve is present with the following relationship: Vrvs−Irvs*Rs=Vfwd−Ifwd*Rs, where Rs is a measured or estimated series resistance of the solar cell. The “corresponding operating points” in particular means that the steps in the reverse pass are carried out in reverse order to that in the forward pass: The first step along the reverse pass corresponds to the last step along the forward pass, the second step along the reverse pass corresponds to the penultimate step along the forward pass, etc. It should be noted here that the reverse curve may, and under certain circumstances must, have further operating points.

To solve this problem numerically, the value (Vrvs−Vfwd)−Rs*(Irvs−Ifwd) is preferably kept as close to zero as possible using a control algorithm, such as a PID control algorithm. In other words, during the reverse pass, the operating points (Vrvs, Irvs) should be determined by means of a control algorithm in such a way that the value Abs((Vrvs−Vfwd)−Rs*(Irvs−Ifwd)) is minimized, where Abs(x) represents the absolute value of the value x.

According to a suitable configuration, the solar cell is illuminated during the forward pass and the reverse pass. However, if the solar cell is not illuminated during the test, the measured curves and the calculated characteristic curve are dark characteristic curves. According to one preferred embodiment, the solar cell is illuminated during the forward pass with a different illumination than during the reverse pass. In this case, different illumination can mean in particular: Different light intensities or illuminances, and/or illumination with different light frequency ranges. In particular, it may also include the procedure in which measurements are carried out in one case with illumination and in the other case in darkness, i.e. completely without illumination.

Advantageously, a first forward pass and a first reverse pass are first carried out with a certain first illumination or in darkness at the solar cell, and a second forward pass and a second reverse pass are then carried out with a second illumination or in darkness. It is also possible to provide further forward passes and reverse passes for further illuminations. For example, the first passes can be carried out in darkness, the second passes can be carried out with illumination of 0.5 sun, and third passes can be carried out with illumination of one sun.

According to a simplified configuration, it may be provided here that both the first forward pass and the first reverse pass are carried out only with the first illumination or in darkness, while only the second reverse pass is then carried out with the second illumination or in darkness without first carrying out the first forward pass. In the latter case, in particular, the necessary information for determining the first voltage range can be determined from the first forward pass and applied to both the first and the second and, if appropriate, the further reverse passes. In this case, the second forward pass and/or the further forward passes can thus be omitted. In the above example, first forward and reverse passes would therefore be carried out in darkness, while only a second reverse pass would be carried out with illumination of 0.5 sun and only a third reverse pass would be carried out with illumination of one sun.

Advantageously, the solar cell test method is used to quickly measure the solar cell with different illuminations. For this purpose, during the illumination of the solar cell with a first illuminance, a first forward current-voltage curve is determined in a first forward pass and a reverse current-voltage curve is determined in a reverse pass, and, during the illumination of the solar cell with a second illuminance, a second forward current-voltage curve is determined in a second forward pass. Correction parameters are then determined from the voltage values and associated current values of the first forward current-voltage curve and the voltage values and associated current values of the reverse current-voltage curve and are used to correct the second forward current-voltage curve in order to calculate a further electrical parameter, in particular a further power parameter, and/or to calculate a further steady-state current-voltage characteristic curve.

Such a procedure can also be used in particular for bifacial solar cells. In particular, the front and back of the bifacial solar cell can be illuminated here with the same illuminance or with different illuminances. During the illumination of a first side of the bifacial solar cell, a first forward current-voltage curve is determined in a first forward pass and a reverse current-voltage curve is determined in a reverse pass. Furthermore, during the illumination of a second side of the bifacial solar cell, a second forward current-voltage curve is determined in a second forward pass. Correction parameters are then determined from the voltage values and associated current values of the first forward current-voltage curve and the voltage values and associated current values of the reverse current-voltage curve and are used to correct the second forward current-voltage curve in order to calculate a further electrical parameter, in particular a further power parameter, of the second side and/or to calculate a steady-state current-voltage characteristic curve of the second side.

Preferably, in the case of a bifacial solar cell, both a forward pass and a reverse pass are carried out in darkness or with illumination of one side, while only a reverse pass is carried out with illumination of the other side.

Preferably, during the reverse pass, for at least one voltage value within the first voltage range, the current flowing through the solar cell due to a voltage change is measured over time and a pass speed of the reverse pass is reduced if a linear drop in the temporal current value curve is determined. In particular, the linear drop shows that the system is in or near the critical area where a breakdown is imminent. The critical area is left again by reducing the pass speed, i.e. in particular reducing the steps between the voltage values. For example, the pass speed of the reverse pass is reduced by (further) reducing the step width, i.e. the spacing between two adjacent voltage values.

Advantageously, during the reverse pass, for at least one voltage value within the first voltage range, the current flowing through the solar cell due to a voltage change is measured over time and the reverse pass is repeated in certain ranges if a drop in the temporal current value curve, which is faster than a linear drop, is determined.

In a further aspect of the invention, a solar cell test method is provided. The solar cell test device is preferably part of a solar cell production system and is arranged, for example, at the end of the system for so-called end-of-line testing. The embodiments and advantages listed above and below in connection with the solar cell test device also apply correspondingly to the solar module test method. This also applies to the computer-readable medium which forms another aspect of the invention.

The invention is explained below on the basis of exemplary embodiments with reference to the figures, in which:

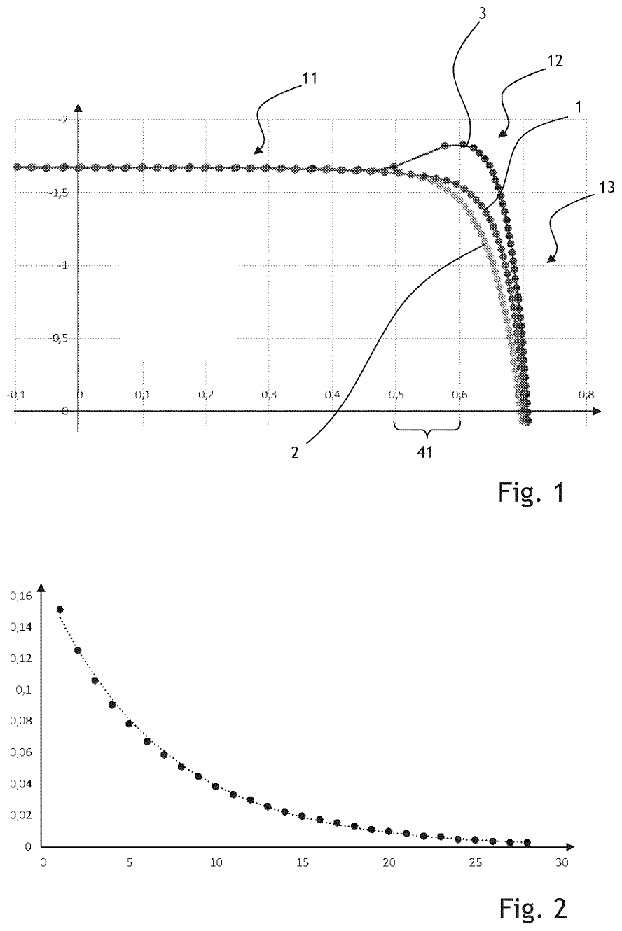

FIG. 1 shows, in a current-voltage diagram, different current-voltage curves which are determined according to the invention;

FIG. 2 shows the temporal profile of a current through the solar cell when a voltage is applied to its contacts outside a critical area; and

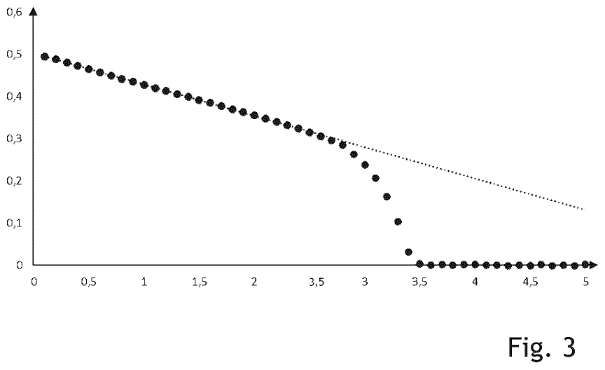

FIG. 3 shows the temporal profile of a current through the solar cell when a voltage is applied to its contacts when the solar cell shows a critical behavior.

FIG. 1 shows a current-voltage diagram in which the voltage is linearly plotted along the x-axis in amperes (A) and the current is linearly plotted along the y-axis in volts (V). The diagram depicts three curves 1, 2, 3 which are measured characteristic curves/curves of a solar cell. They were measured in three different passes. During all passes, the solar cell was illuminated with a light source. The I-U characteristic curve 1 was measured by running through a voltage applied to the solar cell from a voltage value of −0.1 V to a maximum value of approximately 0.7 V. For each voltage value, the current value established in this case was measured. The pairs of voltage value and associated current value determined in this manner were then plotted in the diagram in order to obtain the I-U characteristic curve 1. Each individual point in the I-U characteristic curve represents one of these pairs and thus an operating point of the solar cell. The I-U characteristic curve is obtained in this way if the pass is so slow that a steady-state current value is established for each voltage value. The line that appears to connect the points of the I-U characteristic curve 1 is a curve fit to the points.

The I-U characteristic curve 1 crosses the x-axis at an open-circuit voltage of approximately Voc=0.7 V and the y-axis at a short-circuit current of approximately Isc=1.67 A. It can be roughly divided into three different areas 11, 12, 13. In the first characteristic curve area 11, the characteristic curve runs approximately parallel to the x-axis, whereas it drops steeply in the third characteristic curve area 13. The transition between these two areas 11, 13 is located in a middle, second characteristic curve area 12. This middle characteristic curve area 12 has the operating point of maximum power (MPP) in which the product of current value and voltage value reaches a maximum value. Whereas the characteristic curve/curves 1, 2, 3 in this diagram were determined at an illuminated solar cell, the method works in a corresponding manner for non-illuminated solar cells.

If the voltage values are run through so quickly that a hysteresis effect is formed, then different curve shapes arise in a forward pass compared to a reverse pass, namely a forward curve 2 and a reverse curve 3. While the forward curve 2 runs below the I-U characteristic curve 1, the reverse curve 3 runs above the I-U characteristic curve 1, In the diagram, a first voltage range 41 is also depicted on the x-axis and is here approximately between the voltage values of 0.5 V and 0.6 V. As can be seen on the reverse curve 3, there are two operating points in this first voltage range 41 which are clearly far apart.

1. A solar cell test method, comprising:
applying a varying electrical voltage to a solar cell with which contact has been made and measuring an associated current dependent on the applied voltage, or
applying a varying electrical current to a solar cell with which contact has been made and measuring an associated voltage dependent on the applied current measured,
wherein the applied voltage or the applied current is varied such that the applied or measured voltage first runs through voltage values of a lower voltage in the direction of a higher voltage in a forward pass and then runs through voltage values of a higher voltage in the direction of a lower voltage in a reverse pass, wherein, in the forward pass, the voltage values and the associated current values are arranged on a forward current-voltage curve, and, in the reverse pass, the voltage values and the associated current values are arranged on a reverse current-voltage curve deviating from the forward current-voltage curve, and an electrical parameter of the solar cell is derived from the voltage values and associated current values of the forward current-voltage curve and the voltage values and associated current values of the reverse current-voltage curve, wherein, within a first voltage range during the reverse pass, the voltage values have on average smaller spacings than the voltage ranges adjacent to the first voltage range.

2. The solar cell test method as claimed in claim 1, wherein in the reverse pass within a second voltage range above the first voltage range and/or within a third voltage range below the first voltage range, the voltage values have on average a greater spacing than in the first voltage range, while the voltage values in a fourth voltage range directly below the first voltage range have on average a smaller spacing than in the second and third voltage ranges, but still have on average a larger spacing than in the first voltage range.

3. The solar cell test method as claimed in claim 1, wherein the voltage values have continuously decreasing spacings within the first voltage range in the reverse pass.

4. The solar cell test method as claimed in claim 1, wherein the reverse pass is terminated after running through the first voltage range.

5. The solar cell test method as claimed in claim 1, wherein in that the first voltage range is predetermined.

6. The solar cell test method as claimed in claim 5, wherein the first voltage range is derived from at least one first emitter voltage value.

7. The solar cell test method as claimed in claim 1, wherein the first voltage range is determined by means of the voltage values and associated current values of the forward current-voltage curve.

8. The solar cell test method as claimed in claim 7, wherein those voltage values and associated current values of the forward current-voltage curve, for which deviations of the current values from a short-circuit current value are within a predefined first current difference range, are determined as the first voltage range.

9. The solar cell test method as claimed in claim 8, wherein the forward pass is carried out up to a maximum voltage value, for which an associated current value is measured, wherein the current value range between this current value and the short-circuit current value (Isc) is defined as the total current value range, wherein the first current difference range begins at a distance of a first fraction of the total current value range from the short-circuit current value and ends at a distance of a second fraction of the total current value range from the short-circuit current value.

10. The solar cell test method as claimed in claim 1, wherein one or more capacitance values for the capacitance of the solar cell are determined point by point from one or more voltage values and associated current values of the forward current-voltage curve and/or the reverse current-voltage curve, wherein the voltage values during the reverse pass and/or a pass speed of the reverse pass is/are selected from the capacitance values.

11. The solar cell test method as claimed in claim 1, wherein the reverse pass is paused when the current value reaches the short-circuit current value (Isc) or exceeds the short-circuit current value (Isc), and the reverse pass is then continued when the current value falls below the short-circuit current value (Isc) again.

12. The solar cell test method as claimed in claim 1, wherein the voltage values are selected during the reverse pass in such a way that the solar cell is discharged during the reverse pass at substantially the same rate at which it was charged at the corresponding point in the forward pass.

13. The solar cell test method as claimed in claim 1, wherein the voltage values are selected during the reverse pass in such a way that, for each operating point (Vrvs, Irvs) on the reverse curve, a corresponding operating point (Vfwd, Ifwd) on the forward curve is present with the following relationship: Vrvs−Irvs*Rs=Vfwd−Ifwd*Rs, where Rs is a measured or estimated series resistance of the solar cell.

14. The solar cell test method as claimed in claim 13, wherein during the reverse pass, the voltage values (Vrvs) are determined by means of a control algorithm in such a way that the operating points on the reverse curve are set such that the value Abs((Vrvs−Vfwd)−Rs*(Irvs−Ifwd)) is minimized.

15. The solar cell test method as claimed in claim 1, wherein a steady-state current-voltage characteristic curve (steady-state IV curve) or a part of such a steady-state current-voltage characteristic curve is calculated from the voltage values and associated current values of the forward current-voltage curve and the voltage values and associated current values of the reverse current-voltage curve.

16. The solar cell test method as claimed in claim 1, wherein the solar cell is illuminated during the forward pass and the reverse pass.

17. The solar cell test method as claimed in claim 16, wherein during the illumination of the solar cell with a first illuminance, a first forward current-voltage curve is determined in a first forward pass and a reverse current-voltage curve is determined in a reverse pass, and, during the illumination of the solar cell with a second illuminance, a second forward current-voltage curve is determined in a second forward pass, wherein correction parameters are determined from the voltage values and associated current values of the first forward current-voltage curve and the voltage values and associated current values of the reverse current-voltage curve and are used to correct the second forward current-voltage curve in order to calculate a further electrical parameter and/or to calculate a further steady-state current-voltage characteristic curve.

18. The solar cell test method as claimed in claim 1, wherein during the reverse pass, for at least one voltage value within the first voltage range, the current flowing through the solar cell due to the voltage is measured over time and a pass speed of the reverse pass is reduced if a linear drop in the temporal current value curve is determined.

19. The solar cell test method as claimed in claim 1, wherein during the reverse pass, for at least one voltage value within the first voltage range, the current flowing through the solar cell due to the voltage is measured over time and the reverse pass is repeated in certain ranges if a drop in the temporal current value curve, which is faster than a linear drop, is determined.

20. A solar cell test device comprising a contact-making device having contacts for making contact with a solar cell, a current source or voltage source electrically connected to the contacts and a control device which is designed such that
a varying electrical voltage is applied to the solar cell by means of the contacts and an associated current dependent on the applied voltage is measured, or
a varying electrical current is applied to the solar cell by means of the contacts and an associated voltage dependent on the applied current is measured,
wherein the applied voltage or the applied current is varied such that the applied or measured voltage first runs through voltage values of a lower voltage in the direction of a higher voltage in a forward pass and then runs through voltage values of a higher voltage in the direction of a lower voltage in a reverse pass, wherein, in the forward pass, the voltage values and the associated current values are arranged on a forward current-voltage curve, and, in the reverse pass, the voltage values and the associated current values are arranged on a reverse current-voltage curve deviating from the forward current-voltage curve, and an electrical parameter of the solar cell is derived from the voltage values and associated current values of the forward current-voltage curve and the voltage values and associated current values of the reverse current-voltage curve, wherein, within a first voltage range during the reverse pass, the voltage values have on average smaller spacings than the voltage ranges adjacent to the first voltage range.

21. A computer-readable medium having instructions which can be executed by a computer and, when executed, implement a method as claimed in claim 1.

22. The solar cell test method as claimed in claim 1, wherein the electrical parameter comprises a power parameter.
